(19) United States
(12) Patent Application Publication
(10) Pub. No.: US 2019/0245525 A1
(43) Pub. Date: Aug. 8, 2019

(54) PULSE POWER SOURCE APPARATUS

(71) Applicant: DENSO CORPORATION, Kariya-city (JP)

(72) Inventors: Masaki KANESAKI, Kariya-city (JP); Nobuhisa YAMAGUCHI, Kariya-city (JP); Shoichi TAKEMOTO, Kariya-city (JP)

(21) Appl. No.: 16/267,657

(22) Filed: Feb. 5, 2019

(30) Foreign Application Priority Data
Feb. 6, 2018 (JP) 2018-018954

(51) Int. Cl. H03K 3/02; H02M 3/156

(52) U.S. Cl. CPC H03K 3/02; H02M 3/156

(57) ABSTRACT

A pulse power source apparatus that supplies a drive power to a pulse load circuit that periodically generates pulse current constituted of one or more consecutive pulses from the drive power. The pulse power source apparatus includes a DC voltage generation unit generating DC output voltage supplied to the pulse load circuit, and a pulse load drive signal generation unit generating a drive signal that drives the pulse load circuit to generate the pulse current. The DC output voltage which has dropped due to output of the pulse current is controlled such that a timing at which the DC output voltage reaches a reference potential corresponds to a timing at which a subsequent pulse current is generated, the reference potential being a potential capable of generating the pulse.

### CROSS-REFERENCE TO RELATED APPLICATION

This application is based on and claims the benefit of priority from earlier Japanese Patent Application No. 2018-18954 filed Feb. 6, 2018, the description of which is incorporated herein by reference.

### BACKGROUND

### Technical Field

The present disclosure relates to a pulse power source apparatus.

### Description of the Related Art

A pulse power source apparatus supplying a drive power to a pulse load circuit that generates pulse current is known. The pulse power apparatus is provided in order to supply stable power source voltage to the pulse load circuit.

### SUMMARY

The present disclosure provides a pulse power source apparatus that reduces momentary power and pulsation.

In the pulse power source apparatus, the DC output voltage which drops due to output of the pulse current is controlled such that a timing at which the DC output voltage reaches a reference potential matches a timing at which a subsequent pulse current is generated, the reference potential being set as a potential capable of generating the pulse current.

### BRIEF DESCRIPTION OF THE DRAWINGS

In the accompanying drawings:

FIG. 1 is an overall configuration of a pulse power source apparatus of embodiments of the present disclosure;

FIG. 2 is a control block diagram showing a pulse power source apparatus according to a first embodiment;

FIG. 3 is a graph showing a relationship between the output current and the pulse frequency;

FIG. 4 is a timing diagram showing an operation of the pulse power source apparatus according to the first embodiment;

FIG. 5 is a control block diagram showing a pulse power source apparatus according to a second embodiment;

FIG. 6 is a timing diagram showing an operation of the pulse power source apparatus according to the second embodiment;

FIG. 7 is a control block diagram showing a pulse power source apparatus according to a third embodiment;

FIG. 8 is a timing diagram showing an operation of the pulse power source apparatus according to the third embodiment;

FIG. 9 is a timing diagram showing an operation of the pulse power source apparatus according to the third embodiment;

FIG. 10 is a control block diagram of a pulse power source apparatus according to a fourth embodiment;

FIG. 11 is a timing diagram showing an operation of the pulse power source apparatus according to the fourth embodiment;

FIG. 12 is a timing diagram showing an operation of the pulse power source apparatus according to the fourth embodiment;

FIG. 13 is a control block diagram showing a pulse power source apparatus according to fifth and sixth embodiments;

FIG. 14 is a timing diagram showing a pulse power source apparatus according to a fifth embodiment;

FIG. 15 is a timing diagram showing a pulse power source apparatus according to a sixth embodiment; and

FIG. 16 is a timing diagram showing a conventional pulse power apparatus.

### DETAILED DESCRIPTION OF THE DRAWINGS

With reference to the drawings, hereinafter, embodiments of the pulse power source apparatus will be described. In the embodiments, the same reference numbers are applied to substantially the same configurations, and explanation thereof will be omitted. Note that the first to six embodiments may be referred to as “present embodiment”. The pulse power source apparatus according to the present embodiment supplies a drive power to a pulse load circuit such as a discharge load or a laser device to periodically generate pulse current to the pulse load circuit.

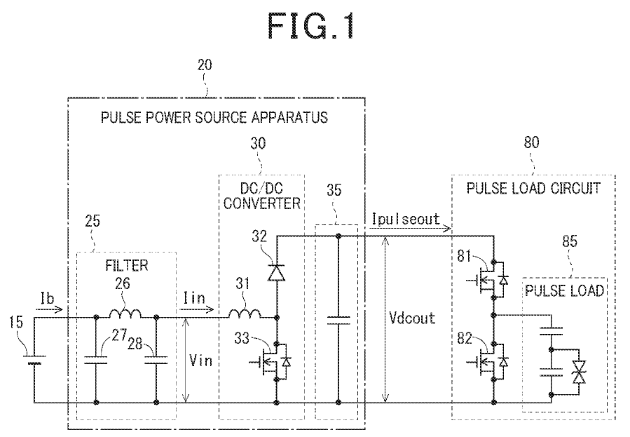

With reference to FIG. 1, firstly, an example of an overall configuration of a conventional pulse power source apparatus will be described. A pulse power source apparatus 20 is provided between a battery 15 as a DC power source and a pulse load circuit 80. The pulse power source apparatus includes a filter 25, a DC/DC converter 30 and a capacitor 35. The filter 25 is configured of a reactor 36 through which a battery current Ib flows, and an LC circuit including capacitors 27 and 28 which are parallelly connected to the battery 15.

The input current Iin after the filter 25 is supplied to the DC/DC converter 30. According to an example shown in FIG. 1, the DC/DC converter 30 serves as a non-insulated boost circuit including an inductor 31, a diode 32 and a switching element 33, and outputs a boosted input voltage Vin by operating the switching element 33. As a DC/DC converter, alternatively, an insulated configuration using a transformer may be employed. The DC output voltage Vdcout outputted by the DC/DC converter 30 is charged into the capacitor 35 and applied to the pulse load circuit 80.

In the pulse load circuit 80, two serially-connected switching elements 81 and 82 are provided between the high voltage line and the low voltage line, and the intermediate point between the switching elements 81 and 82 is connected to the pulse load 85. When the high side switching element 81 turns ON and the low side switching element 82 turns OFF, the pulse current Ipulseout generated in the pulse load circuit 80 flows through the pulse load 85.

For example, the pulse load circuit 80 may be used as a discharge reactor of an ozone generation apparatus that generates ozone by supplying high voltage pulse power between electrodes to react oxygen molecules with oxygen radicals. Hereinafter, the frequency of the pulse current Ipulseout is referred to as “pulse frequency” and a period of the pulse current Ipulseout, i.e. the inverse of the pulse frequency, is referred to as “pulse period”. Note that the higher the pulse frequency, i.e. the shorter the pulse period, the more the amount of generated ozone increases.

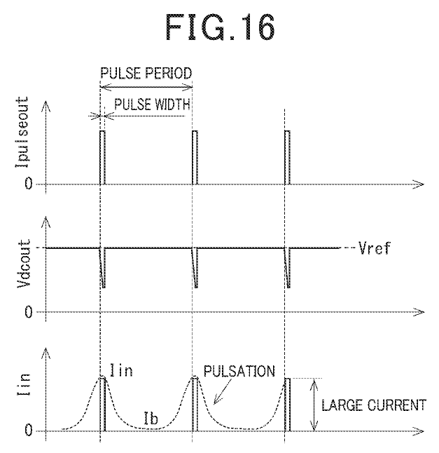

Here, an operation of a conventional pulse power source apparatus is illustrated in a timing diagram of FIG. 16. The horizontal axis of each timing diagram is defined as the time axis, and a label “time” will be omitted in the respective timing diagrams. FIG. 16 illustrates a change in the pulse current Ipulseout, and the output voltage Vdcout and the input current Iin. The input current Iin correlates to the output power, where an amount of the input current Iin reflects to an increase rate of the output voltage Vdcout. Also, in the pulse load circuit 80, a voltage capable of generating pulse current Ipulseout is a reference potential Vref.

When the pulse current Ipulseout is outputted, due to the voltage drop of the output voltage Vdcout, a voltage gap is produced between the reference potential Vref and the Vdcout. This voltage gap is compensated by charging the capacitor 35 with electric charge supplied from the DC/DC converter 30. The relationship between the output voltage V of the DC/DC converter 30, the output current I, electric charge Q and electrostatic capacity of the capacitor 35 and a charge time t is expressed by the following equations (1) and (2).

V=Q/C (1)

Q=I×t (2)

With the equations (1), and (2), recovering the dropped output voltage Vdcout to be the reference potential Vref, the larger the current I, the shorter the charge time t, i.e. recovery time of the output voltage Vdcout. According to the conventional technique, immediately after outputting the pulse current Ipulseout, the DC/DC converter operates to supply large power to the capacitor 35, whereby the output voltage Vdcout recovers.

According to the present embodiment, the pulse width of the pulse current Ipulseout is assumed to be less than or equal to 1 μs, and the pulse period is assumed to be about 10 times of the pulse width, i.e. less than or equal to 10 μs. In this case, in order to stabilize the output voltage Vdcout of the DC/DC converter 30, a large amount of power is necessary. Further, when the voltage of the battery 15 is relatively low, a large amount of current is required to secure the power.

Hence, the input current Iin behaves as a pulsation current which periodically varies between the peak current momentarily flowing at a time when the voltage recovers and the battery current Ib flowing during other periods. Also, since the current capacity need to be increased for the capacitor 35, the reactor of the filter 25 and the like, a problem arises that the size of the pulse power source apparatus may increase.

In this respect, the pulse power source apparatus according to the present embodiment is configured to achieve reduction of the momentary power and prevent the pulsation current from occurring when the output voltage Vdcout of the DC/DC converter 30 recovers, after outputting the pulse current Ipulseout using the pulse load circuit 80. Moreover, the pulse power source apparatus according to the present embodiment avoids the need for a large amount of current thereby suppressing an increase in the current capacity of circuit components. Hence, the size of the pulse power source apparatus is reduced. Hereinafter, the configuration of the pulse power source apparatus according to the present embodiment and the operation example thereof will be described for each embodiment. As a reference number for each pulse power source apparatus of embodiments, the lowest digit subsequent to the number 20 is defined as the corresponding number of the embodiment.

### First Embodiment

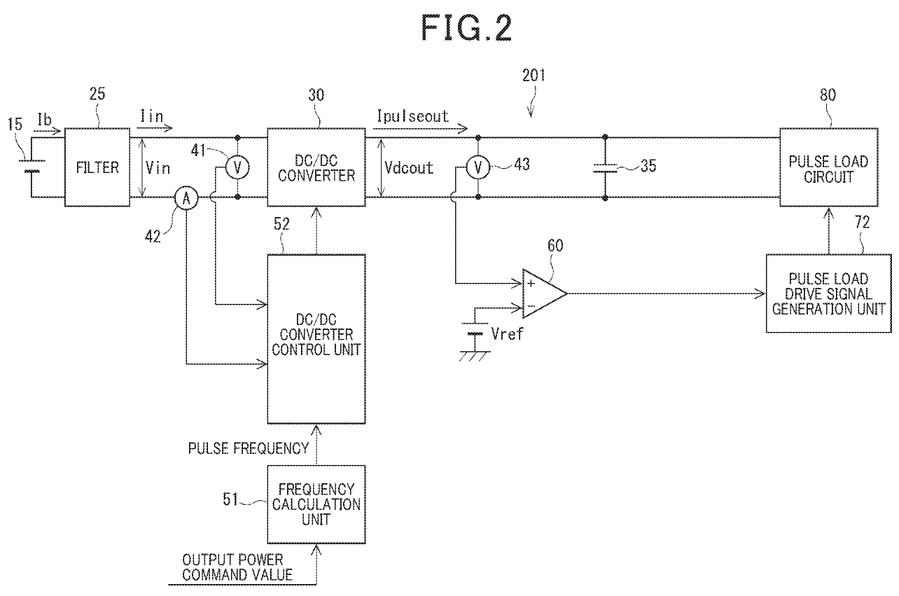

With reference to FIGS. 2 to 4, a pulse power source apparatus according to a first embodiment will be described. As shown in FIG. 2, the pulse power source apparatus 201 is provided with, similar to the overall configuration shown in FIG. 1, a filter 25, a DC/DC converter 30 and a capacitor 35. The DC/DC converter 30 is provided with an input voltage sensor 41 and an input current sensor 42 at the input side thereof, and the output voltage sensor 43 at the output side thereof. A DC/DC converter control unit 52 inputs the detection values corresponding to the input voltage Vin and the input current Iin. A voltage comparator 60 inputs the detection value of the output voltage Vdout and compares the detection value with the reference potential Vref.

As a control configuration of the DC/DC converter 30, the pulse power source apparatus 201 includes a frequency calculation unit 51 and the DC/DC converter control unit 52. As a control configuration of the pulse load circuit 80, a voltage comparator 60 and a pulse load drive signal generation unit 72. The DC/DC converter 30 and the DC/DC converter control unit 52 correspond to “DC voltage generation unit” and “DC voltage generation control unit” respectively.

The frequency calculation unit 51 calculates the pulse frequency of the pulse current Ipulseout based on the output power command commanded by a control apparatus or the like which controls an operational state of the pulse load 85, and notifies the DC/DC converter control unit 52 of the calculated frequency as a “command frequency” or “command period” which is the inverse of the command frequency. Note that the higher the operational requirement of the pulse load 85, the higher the required pulse frequency. As a matter of convenience, the command frequency and the command period are separately described since the command period is useful for a comparison with respect to a time axis in the timing diagram. Actually, either the frequency or the period may be notified as a command value and an inverse calculation may be executed as needed.

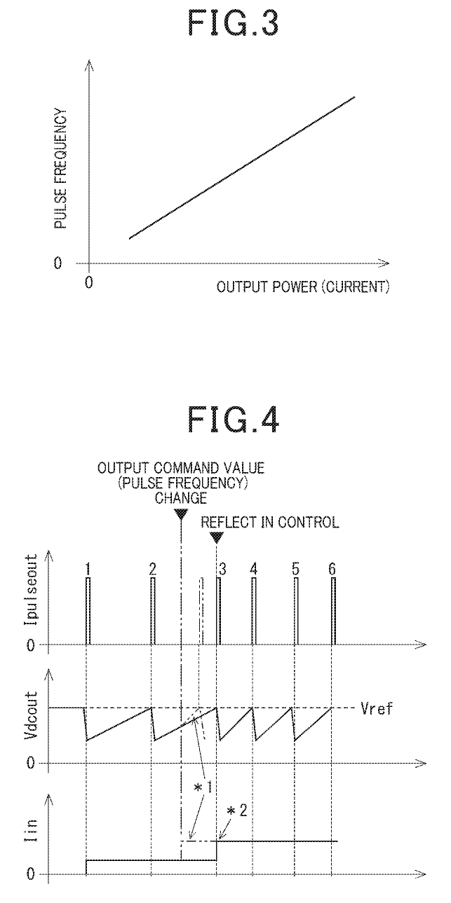

The frequency calculation unit 51 stores, based on a graph shown in FIG. 3, a relationship between the output power command value and the pulse frequency. According to the first embodiment, the charging time of the capacitor 35 with the output current of the DC/DC converter 30 is adjusted to be a pulse period, i.e. the inverse of the pulse frequency. The above-described equation is modified to obtain the following equation (3) which expresses the pulse frequency f.

f=(1/t)=I/Q (3)

With the equation (3), since the pulse frequency is proportional to the output current I, the pulse frequency is proportional to the output power when assuming the output voltage Vdcout is constant. Hence, as shown in the graph of FIG. 3, the pulse frequency has a proportional relationship with respect to the output power command value. When it is assumed that a ratio between the input power and the output power in the DC/DC converter is constant, by using the input power, the output current and the pulse frequency can be indirectly controlled.

The DC/DC converter control unit 52 control unit 52 controls the output power of the DC/DC converter 30 such that a period from when the output voltage Vdcout decreases to when the output voltage Vdcout reaches the reference potential Vref is set to be a command period.

The voltage comparator 60 compares the output voltage Vdcout with the reference potential Vref. The pulse load drive signal generation unit 72 generates a drive signal that drives the pulse load circuit 80 to generate the pulse current Ipulseout. Specifically, according to the first to fourth embodiments, the pulse load drive signal generation unit 72 generates a drive signal when the voltage comparator 60 detects that the output voltage Vdcout reaches the reference potential Vref. In other words, as a trigger event at a time when the difference between the output voltage Vdcout and the reference potential Vref becomes zero, the pulse load drive signal generation unit 72 enables the pulse load circuit 80 to generate the pulse current Ipulseout.

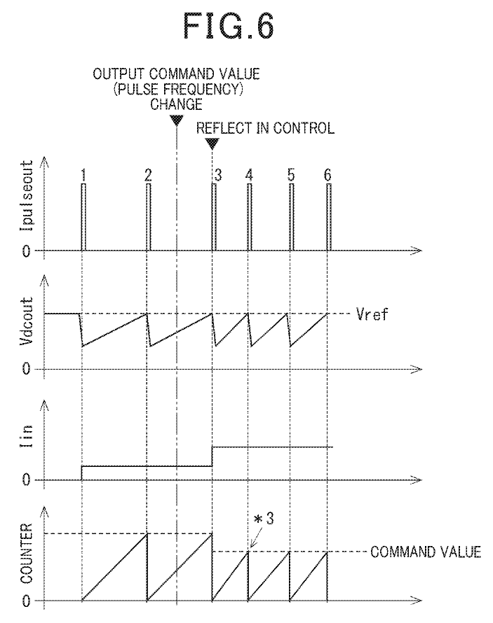

An operation example of a first embodiment will be described with reference to a timing diagram shown in FIG. 4. Similar to FIG. 6 illustrating a prior art technique, FIG. 4 illustrates a change in the output voltage Vdcout and the input current Iin. The input current Iin correlates to the output power, and an amount of the input current Iin is reflected in an increase rate of the output voltage Vdcout.

According to the first to fourth embodiment, at a time when the output voltage Vdcout of the DC/DC converter 30 reaches the reference potential Vref, the pulse current Ipulseout is generated at the pulse load circuit 80 by the drive signal generated by the pulse load drive signal generation circuit. Hence, a timing at which the output voltage Vdcout reaches the reference potential Vdcout necessarily corresponds to a generation timing of the pulse current Ipulseout.

Hereinafter, “output of the pulse current by the DC/DC converter 30” and “generation of the pulse current by the pulse load circuit 80” are omitted and described as “pulse output” and “pulse generation”. Further, a timing when the output voltage Vdcout reaches the reference potential Vref is referred to as “reference potential reach timing”, and a time to reach the reference potential Vref is referred to as “reference potential reach time”.

In the timing diagram, for the sake of convenience, a pulse number is sequentially applied to respective Ipulseout current pulses, starting from pulse number “1”. For example, in the specification, the pulse number is added to the pulse current, such as “first pulse”, “second pulse” and so on. Also, numbers such as (*1), (*2) are added to portions of notes in the timing diagram, which will be quoted in the specification. These pulse numbers and the notes are separately used for each drawing.

In an example shown in FIG. 4, the output power command value is relatively low, the command frequency is high and the command period is long during a period from the first pulse output to the third pulse output. At this time, an increase rate of the output voltage Vdcout is relatively low. On the other hand, during a period from the third pulse output to the sixth pulse output, the output power command value is relatively high, the command frequency is low and the command period is long. At this time, the increase rate of the output voltage Vdcout is relatively high. Thus, the DC/DC converter control unit 52 changes the output power depending on the command frequency.

According to an example shown in FIG. 4, the output power command value is changed to an increase side during a period from the second pulse output to third pulse output. Assuming that the DC/DC converter control unit 52 immediately aquires the change of the output power command value into the control, the operation is indicated by (*1) with a two dot chain line, in which the third pulse is outputted earlier. In this case, the pulse period from the second output to the third output may change unexpectedly.

In order to avoid the above-mentioned problem, in the present embodiment, when the output power command value inputted to the frequency calculation unit 51 is changed, the DC/DC converter control unit 52 acquires the change of the output power command value into the control, at a timing synchronizing to the next output timing of the pulse current Ipulseout. Note that “a timing synchronizing to the output timing” is not limited to a timing the same as the output timing, but includes a timing shifted by a predetermined time from the output timing.

According to an example shown in FIG. 4, the DC/DC converter control unit 52 acquires the change of the output power command value into the control at a time when the command period has elapsed from the second pulse output timing, and increases the input current Iin as indicated by (*2). This change timing is equal to the third pulse output timing. Hereinafter, stable pulse output continues based on the changed output power command value. According to the above-described configuration and operations, the pulse power source apparatus 201 of the first embodiment has the following effects.

(1) According to the pulse power source apparatus 201, a timing at which a dropped output voltage Vdcout of the DC/DC converter 30 (dropped due to output of the pulse current Ipulseout) recovers to reach the reference potential Vref corresponds to a generation timing of the subsequent pulse current Ipulseout. Unlike the prior art technique, the output voltage Vdcout is not immediately recovered to the reference potential Vref, and a large amount of current is prevented from flowing in the power source circuit and current pulsation is prevented from occurring. Hence, the current capacity of circuit components can be reduced and the size of the pulse power source apparatus can be smaller.

(2) According to the first embodiment, the pulse load drive signal generation unit 72 generates the drive signal when the voltage comparator 60 determines that the output voltage Vdcout reaches the reference potential Vref. Hence, according to the pulse power source apparatus 201, the reference potential reach timing of the output voltage Vdcout and the pulse current Ipulseout generation timing can be necessarily the same.

(3) The DC/DC converter control unit 52 controls the output power, depending on the pulse frequency calculated by the frequency calculation unit 51 based on the output power command value, such that the reference potential reach time of the output power voltage Vdcout matches the command period. Accordingly, the pulse power source apparatus 201 appropriately controls the operation of the DC/DC converter 30 depending on the output power command value.

### Second Embodiment

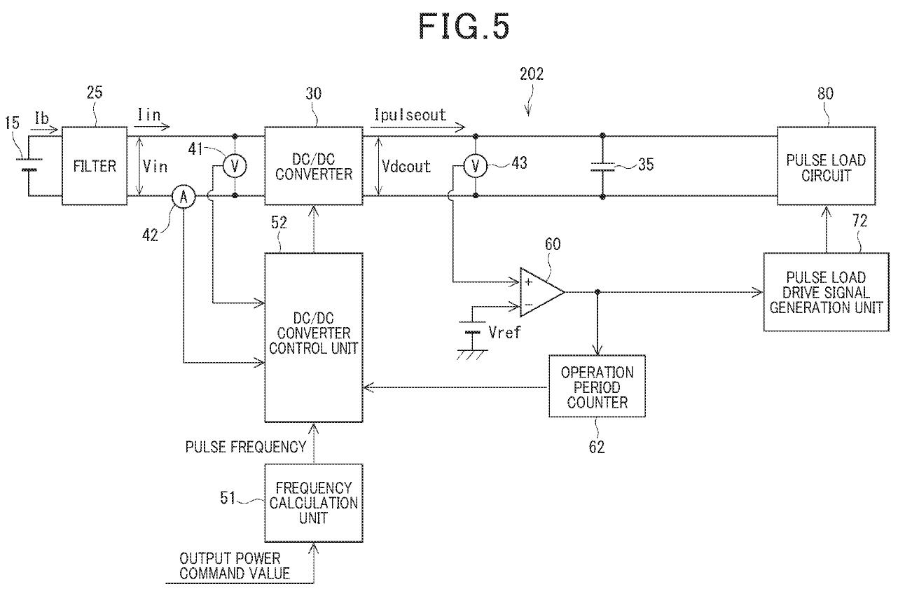

With reference to FIGS. 5 and 6, a pulse power source apparatus according to a second embodiment will be described. The pulse power source apparatus 202 according to the second embodiment shown in FIG. 5 further includes an operation period counter 62 as “operation period supervising unit” compared to the pulse power source apparatus 201 according to the first embodiment. The operation period counter 62 receives a comparison result signal which is sent to the pulse load drive signal generation unit 72 from the voltage comparator 60. The operation period counter 62 monitors an actual operation period from when the output voltage Vdcout of the DC/DC converter 30 decreases to when the output voltage Vdcout reaches the reference potential Vref, and feedbacks the result to the DC/DC converter control unit 52. The DC/DC converter control unit 52 controls the output power of the DC/DC converter 30 such that the deviation between the actual operation period which is feedback from the operation period counter 62 and the command period is close to zero.

In the timing diagram shown in FIG. 6, an operation example of a second embodiment will be described. According to the configuration shown in FIG. 6, the pulse current Ipulseout, the output voltage Vdcout, and the input current Iin are the same as those of the first embodiment shown in FIG. 4, and a count value of the operation period counter 62 is added. The count value of the operation period counter 62 is reset when the pulse current Ipulseout occurs causing the output voltage Vdcout to decrease below the reference potential Vref, and the count value of the operation period counter 62 increases with a constant increase rate as time passes.

In the DC/DC converter 52, when the input current Iin (i.e. output power) is appropriately controlled based on the command frequency, the peak of the count value corresponds to the command value of the counter corresponding to the command period. In the case where the output power command value is changed to an increase side during a period from the second pulse output to the third pulse output, the command value for the count values of the input current Iin and the operation period counter 62 at the third pulse output timing is changed.

In the case where the input current Iin is appropriately changed, as shown in (*3), at the fourth pulse output timing, the peak of the count value corresponds to the changed command value. On the other hand, when the peak of the count value deviates from the command value, the DC/DC converter control unit 52 controls the output power such that the deviation from the command value approaches zero. Thus, the actual operation period can be precisely the same as the command period calculated by the frequency calculation unit 51.

### Third Embodiment

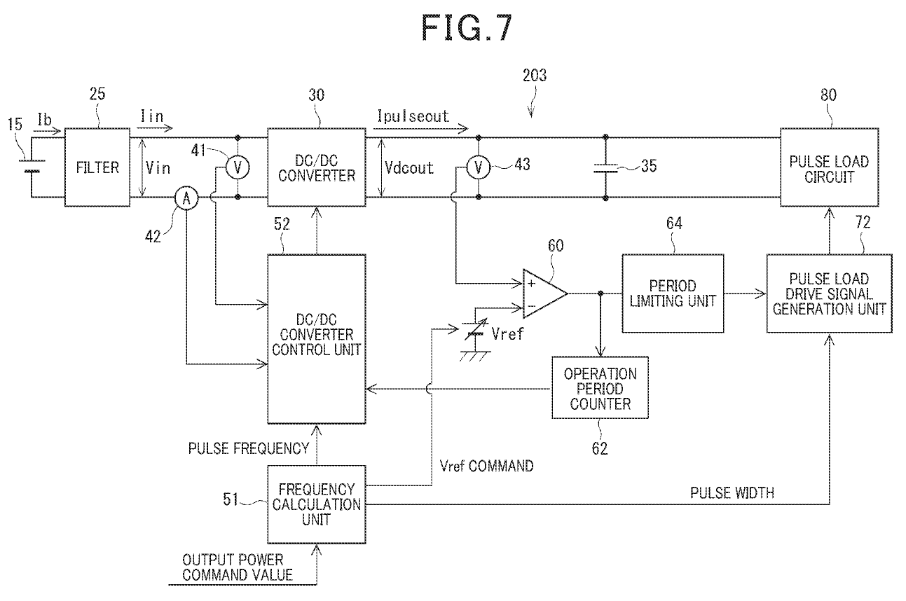

A pulse power source apparatus according to a third embodiment will be described with reference to FIGS. 7 to 9. According to the pulse power source apparatus 203 of the third embodiment shown in FIG. 7, compared to the pulse power source apparatus 202 of the second embodiment, the frequency calculation unit 51 sets the reference potential Vref to be variable and commands the voltage comparator 60 to receive the variable reference potential. Also, the frequency calculation unit 51 sends a pulse width to the pulse load drive signal generation unit 72. Thus, the pulse power source apparatus 203 is able to flexibly generate the waveform of the output voltage Vdcout. Further, a period limiting unit 64 is provided between the voltage comparator 60 and the pulse load drive signal generation unit 72, in order to prevent the pulse current Ipulseout from continuously occurring unintentionally when the reference potential Vref decreases.

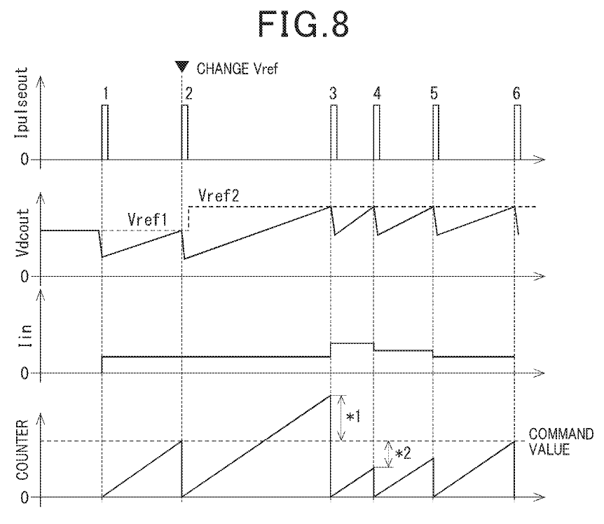

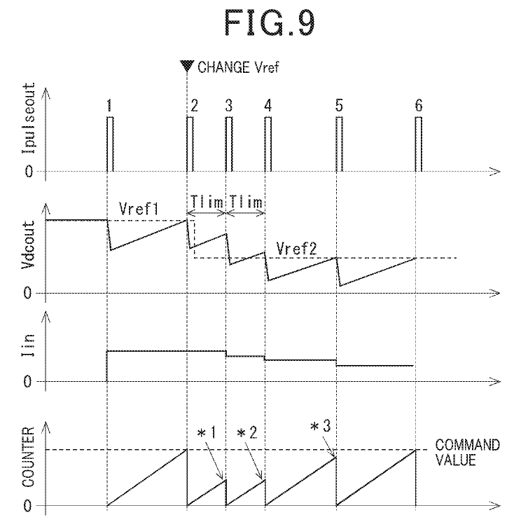

An operation example of the third embodiment is illustrated in timing diagrams shown in FIGS. 8 and 9. In the example of FIG. 8, the reference potential increases from Vref1 to Vref2 at substantially the same timing as the second pulse output timing. On the other hand, since the input current Iin is constant, the reference potential reach time of the output voltage Vdcout increases, and as indicated with (*1), a positive deviation with respect to the command value occurs between the counter value immediately before the third pulse output and the command value.

After the third pulse output, when the input current Iin increases, the reference potential reach time of the output voltage Vdcout becomes too short so that a negative deviation with respect to the command value occurs between the counter value immediately before the fourth pulse output and the command value. Subsequently, after the fourth pulse output, when the input current Iin gradually decreases after the fifth pulse output, the counter value immediately before the sixth pulse output corresponds to the command value. After this timing, stable pulse output continues.

In an example shown in FIG. 9, the reference potential decreases from Vref1 to Vref2 at substantially the same timing as the second pulse output timing. The output voltage Vdcout after the second pulse output is higher than the reference potential Vreg2 and the input current Iin is maintained constant. Since the output voltage Vdcout is higher than the reference potential Vref2 after being changed, if the period limiting unit 64 is not provided, the pulse load drive signal, which is consecutively generated after the second pulse output, immediately outputs the third pulse output.

In this regard, the period limiting unit 64 sets the lower limit pulse period Tlim, thereby disabling the third pulse output during the lower limit pulse period Tlim after the second pulse output. Then, after the lower limit pulse period Tlim has elapsed after the pulse output, the third pulse is outputted. At this time, as indicated by (*1), the counter value does not reach the command value. Immediately after the third pulse output, the output voltage Vdcout is slightly lower than the reference potential Vref2.

After outputting the third pulse, the input current Iin slightly decreases, but reaches the reference potential immediately after the output voltage Vdcout starts to increase. At this moment, since it is within a period from the third pulse output to the lower limit pulse period Tlim, the fourth pulse output is disabled. Then, after the lower pulse period Tlim has elapsed from the third pulse output, the fourth pulse is outputted. Also, at this time, as indicated with (*2), the counter value does not reach the command value. Immediately after outputting the fourth pulse, the output voltage Vdcout is sufficiently below the reference potential Vref2.

After outputting the fourth pulse, the input current Iin further decreases. The output voltage Vdcout reaches the reference potential Vref2 after the lower limit pulse period Tlim has elapsed, and the fifth pulse is outputted. Also at this timing, as indicated with (*3), the counter value does not reach the command value. After outputting the fifth pulse, the input current Iin further decreases. Then, the next timing, at which the output voltage Vdcout subsequently reaches the reference potential Vref and the sixth pulse is outputted, corresponds to the timing at which the counter reaches the command value. Thereafter, stable pulse output is repeated.

As described according to the third embodiment, the reference potential Vref is changed depending on the command of the frequency calculation unit 51, whereby the pulse current Ipulseout can be outputted with a desired potential. However, in a transient period from when the reference potential Vref is changed to when a variation range of the output voltage Vdcout follows the change in the reference potential, a deviation occurs between the reference potential reach time of the output voltage Vdcout and the command period. Specifically, in the case where the reference potential Vref is decreased, by setting the lower limit pulse period Tlim, even when the output voltage Vdcout reaches the reference potential earlier, consecutive pulse output in a short period of time can be avoided.

### Fourth Embodiment

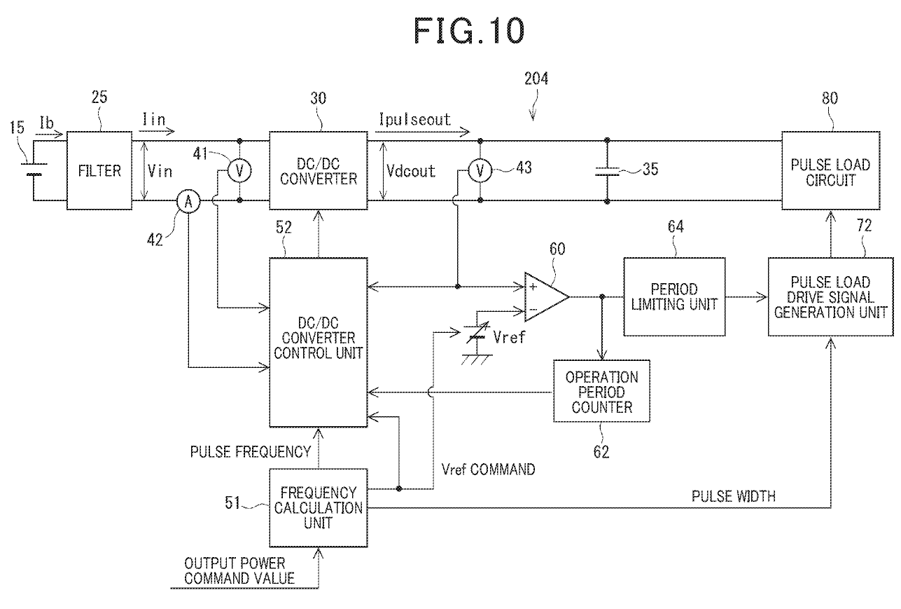

With reference to FIGS. 10 to 12, a pulse power source apparatus according to a fourth embodiment will be described. According to a pulse power source apparatus 204 of the fourth embodiment, compared to the pulse power source apparatus 203 of the third embodiment, the output voltage Vdcout during the pulse output is feedbacked to the DC/DC converter control unit 52 from the output voltage sensor 43. Note that “during the pulse output” is not limited to the period where the pulse current Ipulseout is outputted, but includes a timing immediately before the output. The DC/DC converter control unit 52 controls the output power such that a deviation between the detection value of the feed-backed output voltage Vdcout and the reference potential Vref approaches zero. Further, similar to the pulse power source apparatus 203 according to the third embodiment, the period limiting unit 64 is provided.

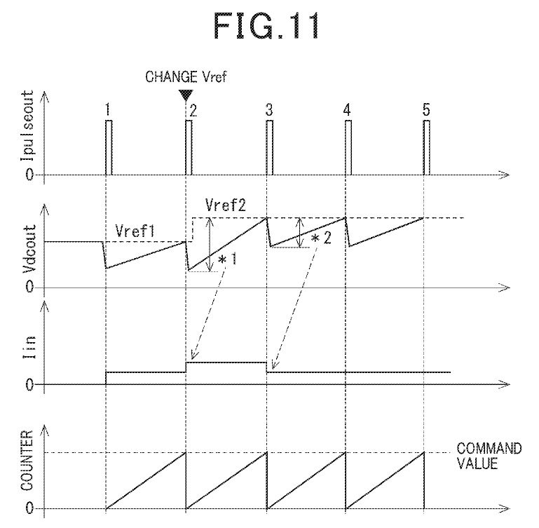

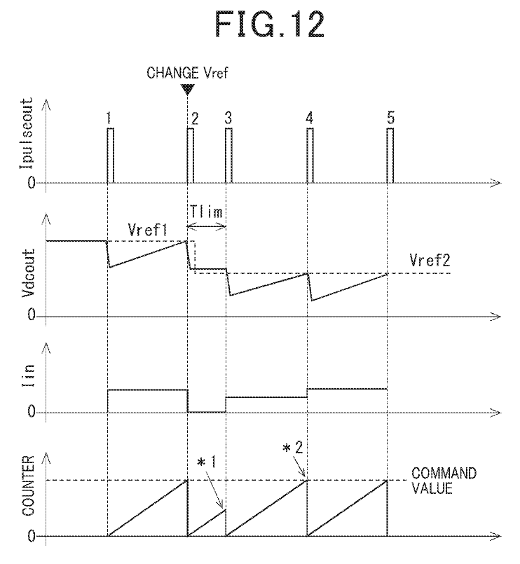

An operation example of the fourth embodiment is shown in the timing diagrams of FIGS. 11 and 12. In an example shown in FIG. 11, the reference potential increases from Vref1 to Vref2. Hence, as indicated with (*1), after the second pulse output, the deviation between the decreased output voltage Vdcout and the changed reference potential Vref2 becomes large. Since the deviation is large, it is expected that the reference potential reach time of the output voltage Vdcout will become longer than the command period.

In this respect, the DC/DC converter control unit 52 increases the input current Iin such that the reference potential reach time of the output voltage Vdcout matches the command period, thereby increasing the output power. As a result, the third pulse is outputted at a timing where the counter value reaches the command value, that is a timing depending on the command period.

After the third pulse output, as indicated with (*2), the deviation between the decreased output voltage Vdcout and the reference potential Vref2 becomes small. Since the deviation is small, it is expected that the reference potential reach time of the output voltage Vdcout is shorter than the command period. In this respect, the DC/DC converter control unit 52 decreases the input current Iin such that the reference potential reach time of the output voltage Vdcout matches the command period, thereby decreasing the output power. As a result, the fourth pulse is outputted at a timing where the counter value reaches the command value, that is a timing depending on the command period.

Thus, according to the fourth embodiment, the output voltage Vdcout is feedbacked to the DC/DC converter control unit 52, whereby the reference potential reach time of the output voltage Vdcout can be the same as the command period even immediately after the reference potential Vref is changed.

According to an example of FIG. 12, the reference potential decreases to the Vref2 from the Vref 1 at a time substantially the same as the second pulse output timing. Since the output voltage Vdcout after the second pulse output is higher than the changed reference potential Vref2, the DC/DC converter control unit 52 sets the input current Iin to be 0, so as not to further increase the output voltage Vdcout. However, in the case where no period limiting unit 64 is provided, the third pulse is immediately outputted by the pulse load drive signal consecutively generated after the second pulse output.

In this regard, the period limiting unit 64 sets the lower limit pulse period Tlim, thereby disabling the third pulse output during the lower limit pulse period Tlim after the second pulse output. Then, after the lower limit pulse period Tlim has elapsed from the pulse output, the third pulse is outputted. Since the third pulse is not outputted by the feedback control, as indicated with (*1), the counter value does not reach the command value. The output voltage Vdcout immediately after the third pulse output is sufficiently below the reference potential Vref2.

The DC/DC converter control unit 52 sets the input current Iin such that the reference potential reach time of the subsequent output voltage Vdcout is the same as the command period based on a deviation between the output voltage Vdcout immediately after the third pulse output and the reference potential Vref2. As a result, as indicated with (*2), the output timing of the fourth pulse equals a timing at which the counter value reaches the command value, that is a timing depending on the command period. Then, subsequent pulse output timings are feedback-controlled to match the command period.

### Fifth Embodiment

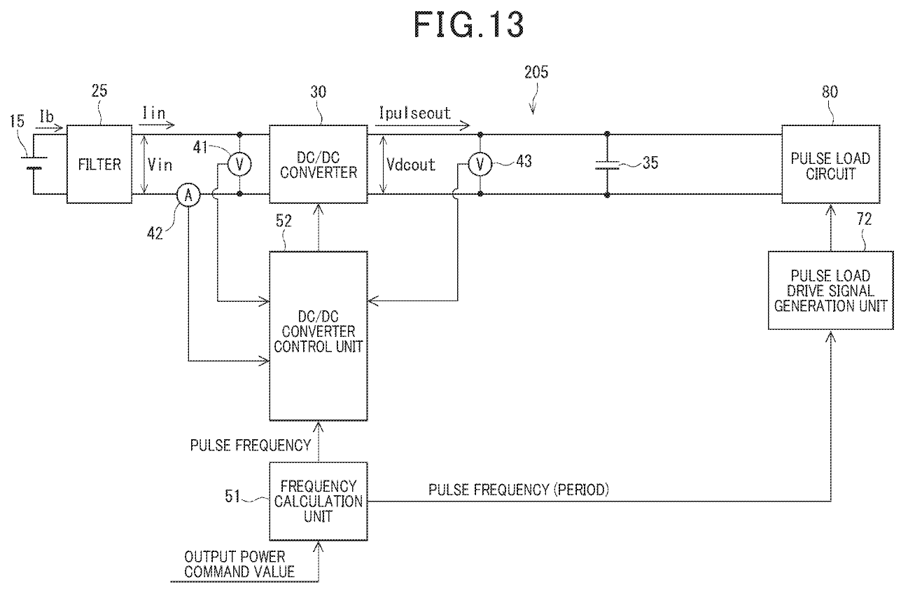

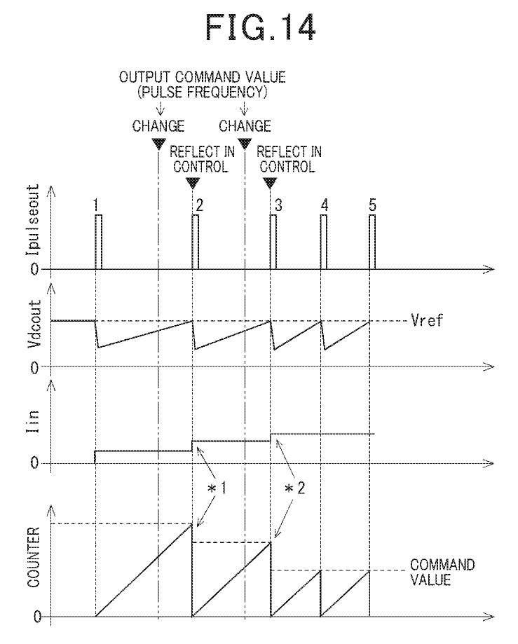

With reference to FIGS. 13 and 14, a pulse power source apparatus according to the fifth embodiment will be described. According to a pulse power source apparatus 205 of a fifth embodiment shown in FIG. 13, unlike the pulse power source apparatus 201 of the first embodiment, the voltage comparator 50 is not included. Also, the frequency calculation unit 51 calculates the pulse frequency based on the output power command value, and notifies the DC/DC converter control unit 52 and the pulse load drive signal generation unit 72 of the pulse frequency as a command frequency or a command period. The pulse load drive signal generation unit 72 generates, regardless of the operation of the DC/DC converter 30, the drive signal depending on the command period to generate the pulse current Ipulseout at the pulse load circuit 80.

The DC/DC converter control unit 52 controls the output power of the DC/DC converter 30 such that the reference potential reach time of the subsequent output voltage Vdcout is the same as the command period. Moreover, according to an example shown in FIG. 13, the output voltage Vdcout during the pulse output is feedbacked to the DC/DC converter control unit 52. This feedback control is not necessary. However, a use of the feedback control allows the output voltage Vdcout to be appropriately adjusted.

An operation example according to the fifth embodiment is shown in the timing diagram of FIG. 14. The output power command value at the first pulse output is relatively low and the command period is relatively long. In the middle of the period from the first pulse output to the second pulse output, the output power command value is changed a first time, and the change in the output power command value is reflected to the control at the second pulse output timing. At this time, in the DC/DC converter control unit 52, as indicated with (*1), the input current Iin is changed to increase and the counter command value is changed to decrease. Also, in the pulse load drive signal generation unit 72, a generation timing of the subsequent drive signal is changed. Thus, when the output power command value is changed, the changed value is reflected to the control at a time synchronizing to the subsequent pulse output timing, whereby the pulse frequency is stabilized.

Subsequently, the output power command value is changed as a second time, in the middle of a period from the second pulse output to the third pulse output, so as to further increase the output power command value, and the changed value is reflected in the control at the third pulse output timing. At this time, in the DC/DC converter control unit 52, as indicated with (*2), the input current Iin is changed to further increase and the counter command value is changed to further decrease. Also, in the pulse load drive signal generation unit 72, the generation timing of the subsequent drive signal is changed again.

According to the above-described first to fourth embodiments, the pulse load drive signal generation unit 72 generates the drive signal at a timing where the output voltage Vdcout of the DC/DC converter reaches the reference potential to generate the pulse current Ipulseout at the pulse load circuit 80. In other words, the pulse load drive signal generation unit 72 merely follows the operation result of the DC/DC converter 30.

In contrast, according to the fifth embodiment, based on the command frequency or the command period calculated by the frequency calculation unit 51, the DC/DC converter control unit 52 and the pulse load drive signal generation unit 72 cooperatively operate to control both of the reference potential reach time and the generation timing of the pulse current Ipulseout. Even in this configuration, the pulse power source apparatus 205 reduces momentary power and also suppresses pulsation, whereby appropriate control can be executed depending on the output power command value.

### Sixth Embodiment

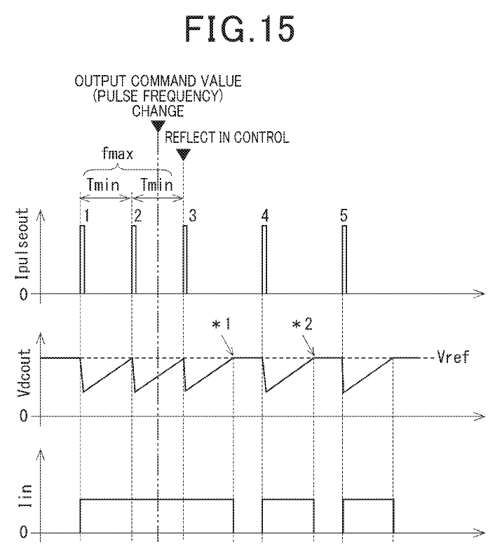

With reference to FIG. 15, a pulse power source apparatus according to a sixth embodiment will be described. The configuration of the pulse power source apparatus according to the sixth embodiment is similar to that of the pulse power source apparatus 205 according to the fifth embodiment, and only the operation of the DC/DC converter control unit 52 is different from the fifth embodiment. In the sixth embodiment, the output voltage Vdcout detected by the output voltage sensor 43 may not be feedbacked to the DC/DC converter control unit 52.

According to the sixth embodiment, the DC/DC converter control unit 52 switches the output power of the DC/DC converter 30 which is set to a fixed value, between the ON state and OFF state. In other words, unlike the fifth embodiment in which the output power is changed from 0 to the maximum value in a multi-step manner, the output power is changed in a two step manner where either 0 or a fixed value is used according to the sixth embodiment. The fixed value of the output power is set to be the output power corresponding to the maximum pulse frequency of the pulse current Ipulseout or more. Note that the fixed value of the output power may preferably be set to a value having a margin with respect to the maximum rating.

The DC/DC converter 30 outputs fixed power after the output voltage Vdcout is lowered because of occurrence of the pulse current Ipulseout. According to a configuration in which the output voltage Vdcout is feedbacked using the output voltage sensor 43, the DC/DC converter 30 stops operation during a period from when the output voltage Vdcout actually reaches the reference potential to when the command period is completed. According to a configuration in which the output voltage Vdcout is not feedbacked, the DC/DC converter 30 stops operation during a period from when the output voltage Vdcout is estimated, based on the output power, to reach the reference potential Vref to when the command period is completed.

An operation example of the sixth embodiment is shown in the timing diagram of FIG. 15. The input current Iin is constant value or 0. When the input current Iin is constant, an increase rate of the output voltage Vdcout is constant, and when the input current Iin is 0, the output voltage Vdcout does not change. During a period from the first pulse output to the third pulse output, the output power command value corresponding to the maximum pulse frequency fmax is determined and outputted as a pulse at a minimum period Tmin. At this time, the output voltage Vdcout reaches the reference potential Vref at a pulse output timing.

In the middle of a period from the second pulse output to the third pulse output, the output command value is changed, and the changed value is reflected to the control of the DC/DC converter unit 52 at a timing synchronizing to the third pulse output timing. Thus, the command frequency is changed to a value lower than the maximum pulse frequency Fnnax, and the command period is set to be longer than the minimum pulse period Tmin.

Accordingly, as indicated with (*1) and (*2), after the output voltage Vdcout reaches the reference potential Vref, the DC/DC converter 30 stops the operation until the next pulse comes. Thus, according to the sixth embodiment, since the DC/DC converter 30 always operates with an output power lower than or equal to the rated power, that is, operates within a high efficiency operating range, the operating efficiency is improved.

### Other Embodiment

(a) DC voltage generation unit is not limited to a DC/DC converter that coverts DC voltage to DC voltage, but may be configured of an AC/DC converter that converts AC voltage to DC voltage.

(b) In a system in which the operational requirement to the pulse load 85 is constant and the output power command value is constant, the frequency calculation unit 51 and the DC/DC converter control unit 52 may not be provided. In this case, similar to the first to fourth embodiments, the pulse load drive signal generation unit 72 may generate a drive signal at a timing where the output voltage Vdcout reaches the reference potential Vref, and may generate the pulse current Ipulseout at the pulse load circuit 80.

(c) DC/DC converter 30 is not limited to a configuration in which one pulse current Ipulseout is outputted per one time pulse output, but a plurality of pulse current Ipulseout may be outputted.

(d) The “operation period supervising unit” is not limited to a configuration in which a counter discretely counts time in a small unit, but a configuration may be used in which an operation period is supervised based on a sensor value of the analog signal outputted by an output voltage sensor 43.

(e) When the output power command value is changed, a timing at which the changed value is reflected to the control of the DC/DC converter is not limited to the immediately next pulse output timing, but may be a timing synchronizing to a timing which is after the second time pulse output timing. Further, the control may be changed in the middle of the pulse output timing as long as cooperative operation between the DC/DC converter 30 and the pulse load circuit 80 is possible.

The present disclosure is not limited to the above-described embodiments, but various modification can be made without departing the technical scope of the present disclosure.

As described, a power source apparatus for a pulse load circuit is known. The power source apparatus detects whether or not the output voltage of the DC/DC converter varies by comparing detection signals of a voltage detection circuit and a current detection circuit with a reference signal. When the output voltage varies, the operational amplifier controls the output voltage and the output current of the DC/DC converter such that the DC voltage to the pulse load circuit to be constant.

When pulse current is flowing, the output voltage of DC voltage generation device such as DC/DC converter rapidly decreases. With conventional power source apparatuses, the output voltage recovers rapidly after dropping. In order to stabilize the voltage of the pulse power source, the DC voltage generation device is required to output high output power. In the case where the input voltage to the DC voltage is relatively low, a large amount of current is necessary to secure the required power output. Hence, a momentary current flows in the power circuit and causes pulsation, and also the current capacity of the circuit components is required to increase, and so the size of the pulse power source apparatus increases. However, according to the above-mentioned apparatus, reduction of a momentary power or prevention of a pulsation cannot be achieved.

In this respect, according to the pulse power source of the present disclosure, the output voltage is controlled such that a timing at which a dropped output voltage of the DC voltage generation unit (which dropped due to output of the pulse current) recovers to reach the reference potential (Vref), corresponds to a generation timing of the subsequent pulse current. As a first aspect, the DC voltage generation unit controls, after the output voltage is lowered due to output of the pulse current, the output voltage to gradually recover to the reference potential until the subsequent pulse current generation timing comes. Hence, a large current is prevented from flowing through the power source circuit and also pulsation is prevented from occurring. As a result, the current capacity of circuit components can be reduced and the size of the pulse power source apparatus can be smaller.

Preferably, the pulse source apparatus according to a first aspect further include a voltage comparator (60) that compares the DC output voltage of the DC voltage generation unit and the reference potential. The pulse load drive signal generation unit is configured to generate the drive signal when the voltage comparator detects that the DC output voltage reaches the reference potential. Therefore, according to the pulse power source apparatus of the first aspect, a timing at which the output voltage reaches the reference potential necessarily corresponds to a generation timing of the pulse current

According to a configuration of the first aspect, the pulse power source apparatus further includes a DC voltage generation control unit (52) that controls an output power of the DC voltage generation unit, and a frequency calculation unit (51). The frequency calculation unit calculates a pulse frequency of the pulse current based on an output power command and notifies the DC voltage generation control unit of a calculated frequency as a command frequency or a command period which is the inverse of the command frequency. The DC voltage generation control unit is configured to control the output power of the DC voltage generation unit such that a period from when the DC output voltage decreases to when the DC output voltage reaches the reference potential matches the command period.

According to the configuration, the DC voltage generation control unit adjusts the output power of the DC voltage generation unit based on the required output power command value. Hence, the pulse power source generation apparatus reduces momentary power and also suppresses pulsation, whereby appropriate control can be performed depending on the output power command value.

Alternatively, another configuration of the first aspect further includes a DC voltage generation control unit (52) that controls an output power of the DC voltage generation unit, and a frequency calculation unit (51). The frequency calculation unit (51) calculates a pulse frequency of the pulse current based on an output power command, and notifies the DC voltage generation control unit and the pulse load drive signal generation unit of a calculated frequency as a command frequency or a command period which is the inverse of the command frequency. The pulse load drive signal generation unit is configured to generate the drive signal based on the command period. The DC voltage generation control unit is configured to control the output power of the DC voltage generation unit such that a period from when the DC output voltage decreases to when the DC output voltage reaches the reference potential matches the command period.

According to this configuration, based on the command frequency or the command period calculated by the frequency calculation unit, the DC voltage generation unit and the pulse load drive signal generation unit cooperatively operate to control both of the reference potential reach time and the generation timing of the pulse current. Even in this configuration, the pulse power source apparatus is able to reduce momentary power and also suppress pulsation, whereby appropriate control can be executed depending on the output power command value.

A pulse power source apparatus according to a second aspect of the present disclosure includes a DC voltage generation unit (30), a pulse load drive signal generation unit (72), a DC voltage generation control unit (52), and a frequency calculation unit (51). The DC voltage generation unit generates a DC output voltage (Vdcout) supplied to the pulse load circuit. The pulse load drive signal generation unit generates a drive signal that drives the pulse load circuit to generate the pulse current. The DC voltage generation control unit switches an output power of the DC voltage generation unit, which is set to a fixed value, between an ON state and OFF state. The frequency calculation unit calculates a pulse frequency of the pulse current based on an output power command and notifies the DC voltage generation control unit and the pulse load drive signal generation unit of a calculated frequency as a command frequency or a command period which is the inverse of the command frequency.

The pulse load drive signal generation unit is configured to generate the drive signal based on the command period. The DC voltage generation unit is configured to output, after the DC output voltage is lowered due to output of the pulse current, a fixed power larger than an output power corresponding to a maximum pulse frequency of the pulse current. Also, the DC voltage generation unit is configured to stop operation during a period after detection or estimation of the output voltage having reached a reference potential, until completion of the command period. The reference potential is a potential capable of generating a pulse.

According to the pulse power source apparatus of the second aspect, conforming to the maximum pulse frequency of the pulse current where the pulse load circuit is capable of generating the pulse current, the output power of the DC voltage generation unit is set to a fixed value which is smaller than or equal to the maximum rating. In the case where the command frequency is less than the maximum pulse frequency, the DC voltage generation unit stops operation after the output voltage reaches the reference potential, until the pulse current is generated. Accordingly, since the DC voltage generation unit always operates with an output power lower than or equal to the rated power, that is, operates within a high efficiency operating range, the operating efficiency is improved.

What is claimed is:

1. A pulse power source apparatus that supplies a drive power to a pulse load circuit, the pulse load circuit periodically generating a pulse current constituted of one or more consecutive pulses from the drive power, the apparatus comprising:
a DC voltage generation unit generating a DC output voltage supplied to the pulse load circuit; and
a pulse load drive signal generation unit generating a drive signal that drives the pulse load circuit to generate the pulse current, wherein
the DC output voltage which drops due to output of the pulse current is controlled such that a timing at which the DC output voltage reaches a reference potential corresponds to a timing at which a subsequent pulse current is generated, the reference potential being set as a potential capable of generating the pulse current.

2. The pulse power source apparatus according to claim 1, wherein
the apparatus further comprises a voltage comparator that compares the DC output voltage of the DC voltage generation unit and the reference potential; and
the pulse load drive signal generation unit is configured to generate the drive signal when the voltage comparator detects that the DC output voltage reaches the reference potential.

3. The pulse power source apparatus according to claim 2, wherein
the apparatus further comprises:
a DC voltage generation control unit that controls an output power of the DC voltage generation unit; and
a frequency calculation unit that calculates a pulse frequency of the pulse current based on an output power command and notifies the DC voltage generation control unit of a calculated frequency as a command frequency or a command period which is the inverse of the command frequency,
the DC voltage generation control unit is configured to control the output power of the DC voltage generation unit such that a period from when the DC output voltage decreases to when the DC output voltage reaches the reference potential matches the command period.

4. The pulse power source apparatus according to claim 3, wherein
the apparatus further comprises an operation period supervising unit that supervises an actual operation period from when the DC output voltage of the DC voltage generation unit decreases to when the DC output voltage reaches the reference potential, and feedbacks a supervising result to the DC voltage generation control unit; and
the DC voltage generation control unit is configured to control the output power of the DC voltage generation unit such that a deviation between the actual operation period feedbacked from the operation period supervising unit and the command period is close to zero.

5. The pulse power source apparatus according to claim 3, wherein
the frequency calculation unit is configured to set the reference potential to be variable and command the voltage comparator to receive the variable reference potential.

6. The pulse power source apparatus according to claim 1, wherein
the apparatus further comprises:
a DC voltage generation control unit that controls an output power of the DC voltage generation unit; and
a frequency calculation unit that calculates a pulse frequency of the pulse current based on an output power command, and notifies the DC voltage generation control unit and the pulse load drive signal generation unit of a calculated frequency as a command frequency or of a command period which is the inverse of the command frequency,
the pulse load drive signal generation unit is configured to generate the drive signal based on the command period; and
the DC voltage generation control unit is configured to control the output power of the DC voltage generation unit such that a period from when the DC output voltage decrease to when the DC output voltage reaches the reference potential is set to be the command period.

7. The pulse power source apparatus according to claim 3, wherein
the DC output voltage of the DC voltage generation unit while the pulse current is being outputted is feedbacked to the DC voltage generation control unit; and
the DC voltage generation control unit is configured to control the output power of the DC voltage generation unit such that a deviation between the feedbacked DC output voltage and the reference potential is close to zero.

8. A pulse power source apparatus that supplies a drive power to a pulse load circuit, the pulse load circuit periodically generating pulse current constituted of one or more consecutive pulses with the drive power, the apparatus comprising:
a DC voltage generation unit generating DC output voltage supplied to the pulse load circuit;
a pulse load drive signal generation unit generating a drive signal that drives the pulse load circuit to generate the pulse current;
a DC voltage generation control unit that switches an output power of the DC voltage generation unit, which is set to a fixed value, between an ON state and an OFF state; and
a frequency calculation unit that calculates a pulse frequency of the pulse current based on an output power command and notifies the DC voltage generation control unit and the pulse load drive signal generation unit of a calculated frequency as a command frequency or a command period which is the inverse of the command frequency, wherein
the pulse load drive signal generation unit is configured to generate the drive signal based on the command period; and
the DC voltage generation unit is configured to output, after the DC output voltage is lowered due to outputting of the pulse current, a fixed power larger than an output power corresponding to a maximum pulse frequency of the pulse current, and stop operation during a period after detection or estimation of the output voltage having reached a reference potential, until completion of the command period, the reference potential being a potential capable of generating a pulse.

9. The pulse power source apparatus according to claim 3, wherein
when the output power command value inputted to the frequency calculation unit is changed, the DC voltage generation control unit acquires the change of the output power command value into the control, at a timing synchronizing to subsequent output timing of the pulse current.
